(19) United States
(12) Patent Application Publication
(10) Pub. No.: US 2025/0311126 A1
(43) Pub. Date: Oct. 2, 2025

(54) ELECTRONIC DEVICE HOUSING AND ELECTRONIC DEVICE

(71) Applicant: Fujitsu Limited, Kawasaki-shi (JP)

(72) Inventor: Naomi FUKUNAGA, Kawasaki (JP)

(73) Assignee: Fujitsu Limited, Kawasaki-shi (JP)

(21) Appl. No.: 19/037,514

(22) Filed: Jan. 27, 2025

(30) Foreign Application Priority Data
Mar. 28, 2024 (JP) 2024-054759

(51) Int. Cl. H05K 5/02

(52) U.S. Cl. CPC H05K 5/0221; H05K 5/0247

(57) ABSTRACT

An electronic device housing includes: a lever that is rotatably attached to an insertion portion into which an electronic unit is to be inserted; a movable rail that supports the electronic unit so as to be slidable in an insertion direction within the insertion portion; a guide member that guides the movable rail so as to be movable up and down with respect to the insertion portion; a first pin that is provided in the lever and rotates the lever by being moved toward a far side of the insertion portion; and a second pin that is provided in the lever and pushes up the movable rail in accordance with the rotation.

### CROSS-REFERENCE TO RELATED APPLICATION

This application is based upon and claims the benefit of priority of the prior Japanese Patent Application No. 2024-54759, filed on Mar. 28, 2024, the entire contents of which are incorporated herein by reference.

### FIELD

The embodiment discussed herein is related to an electronic device housing and an electronic device.

### BACKGROUND

There is an electric circuit storage housing having a case position determination mechanism including a lock lever rotatably supported by a support shaft provided on a case side plate and a guide plate provided on a housing side plate. In this electric circuit storage housing, an opening portion which is elongated toward a far side is formed in the guide plate, and a lock lever action portion is formed at one end portion of the lock lever. With insertion and removal of an electric circuit mounting case, the lock lever action portion is engaged with the opening portion and moves forward and backward. A detachment position setting portion and an inspection position setting portion are formed in the opening portion, and when the electric circuit mounting case is pulled out, the lock lever action portion is locked to a recess portion. The other end portion of the lock lever protrudes outward from a slit hole of a front panel, and a position of the other end portion of the lock lever within the slit hole corresponds to a mounting position of the electric circuit mounting case.

Japanese Laid-open Patent Publication No. 2011-114298 is disclosed as related art.

### SUMMARY

According to an aspect of the embodiments, an electronic device housing includes: a lever that is rotatably attached to an insertion portion into which an electronic unit is to be inserted; a movable rail that supports the electronic unit so as to be slidable in an insertion direction within the insertion portion; a guide member that guides the movable rail so as to be movable up and down with respect to the insertion portion; a first pin that is provided in the lever and rotates the lever by being moved toward a far side of the insertion portion; and a second pin that is provided in the lever and pushes up the movable rail in accordance with the rotation.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an electronic device including an electronic device housing according to a first embodiment;

FIG. 2 is a partially enlarged perspective view illustrating the electronic device including the electronic device housing according to the first embodiment;

FIG. 3 is a side view illustrating a movable rail and a lever of the electronic device housing according to the first embodiment;

FIG. 4 is a partially cutaway perspective view illustrating the electronic device including the electronic device housing according to the first embodiment in a state where an electronic unit is inserted into an insertion portion;

FIG. 5 is a partially cutaway perspective view illustrating the electronic device including the electronic device housing according to the first embodiment in a state where the electronic unit is inserted into the insertion portion;

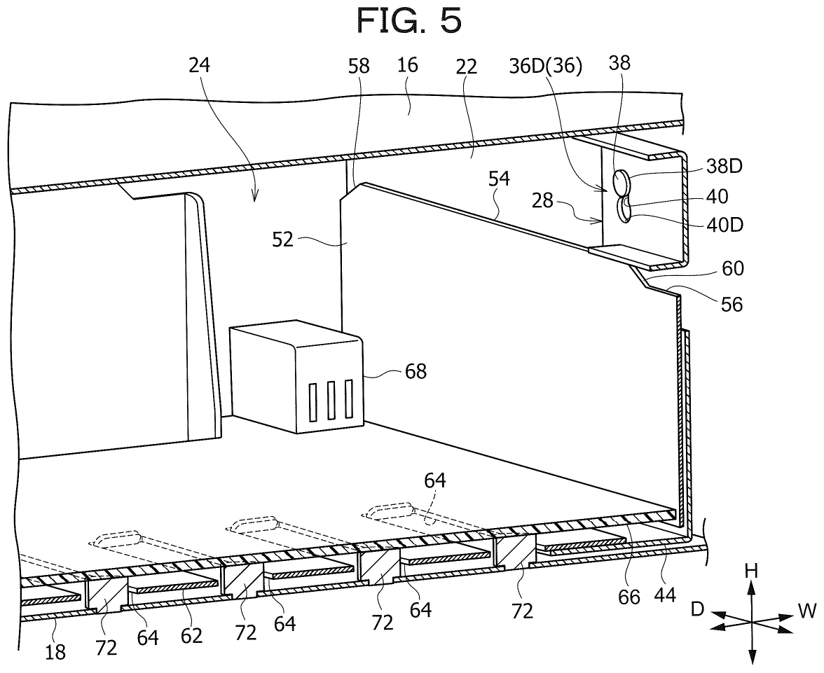

FIG. 6 is an explanatory diagram illustrating the electronic device including the electronic device housing according to the first embodiment in an initial state where the electronic unit is to be inserted into the insertion portion;

FIG. 7 is an explanatory diagram illustrating the electronic device including the electronic device housing according to the first embodiment in a state where the electronic unit is being inserted into the insertion portion; and

FIG. 8 is an explanatory diagram illustrating the electronic device including the electronic device housing according to the first embodiment in a state where the electronic unit is inserted in the insertion portion.

### DESCRIPTION OF EMBODIMENTS

An electronic unit is supported to be slidable by a rail member or the like with respect to an insertion portion of a housing of an electronic device, and thus, the electronic unit may be positioned and inserted at a predetermined position with respect to the insertion portion.

However, in a case where there is an obstacle such as a projection within the insertion portion, a clearance is provided between the electronic unit and the obstacle such that the electronic unit does not interfere with the obstacle. With this clearance, a height of the electronic unit is reduced, and the number, sizes, and the like of components that may be mounted on the electronic unit are limited.

In an aspect, an object of the technology disclosed in the present application is to make it possible to insert an electronic unit at a predetermined position of an insertion portion without reducing a size of the electronic unit even in a case where there is an obstacle within the insertion portion.

An electronic device housing 12 according to a first embodiment and an electronic device 10 including this electronic device housing 12 will be described in detail with reference to the drawings.

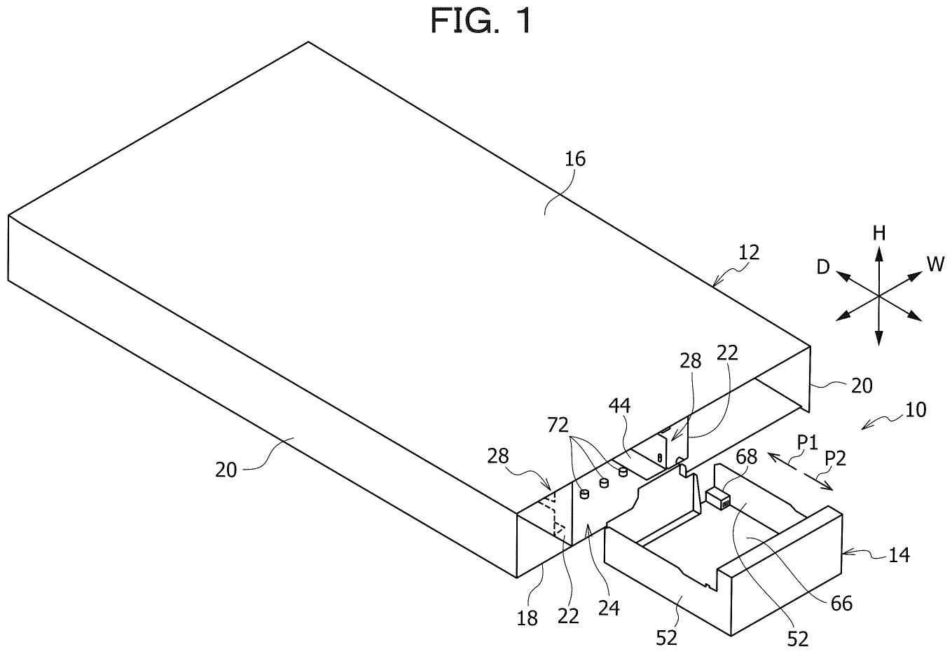

FIG. 1 illustrates the electronic device 10 according to the first embodiment. The electronic device 10 includes the electronic device housing 12 and an electronic unit 14. A width direction, a depth direction, and a height direction of the electronic device housing 12 are indicated by an arrow W, an arrow D, and an arrow H, respectively. The width direction of the electronic device housing 12 is also a left-right direction of the electronic device housing 12. In the depth direction of the electronic device housing 12, a direction toward a far side is an insertion direction of the electronic unit 14 into the electronic device housing 12, and a direction toward a near side is a removal direction of the electronic unit 14 from the electronic device housing 12. Arrow P1 and arrow P2 indicate the insertion direction of the electronic unit 14 and the removal direction of the electronic unit 14, respectively.

The electronic device housing 12 includes a top plate 16, a bottom plate 18, and a pair of left and right side plates 20. A plurality of partition walls 22 are provided in parallel with the side plates 20 in an intermediate portion in the width direction. An insertion portion 24 is formed by the top plate 16, the bottom plate 18, and the two partition walls 22. The electronic unit 14 is inserted into and removed from the insertion portion 24. In the insertion portion 24, one or a plurality of projections 72 protrude upward from the bottom plate 18.

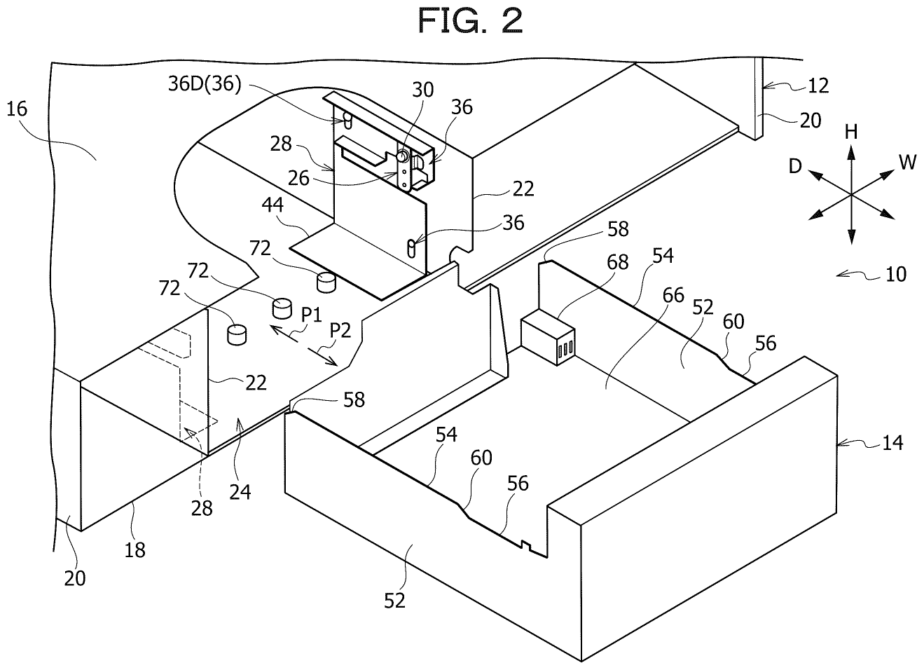

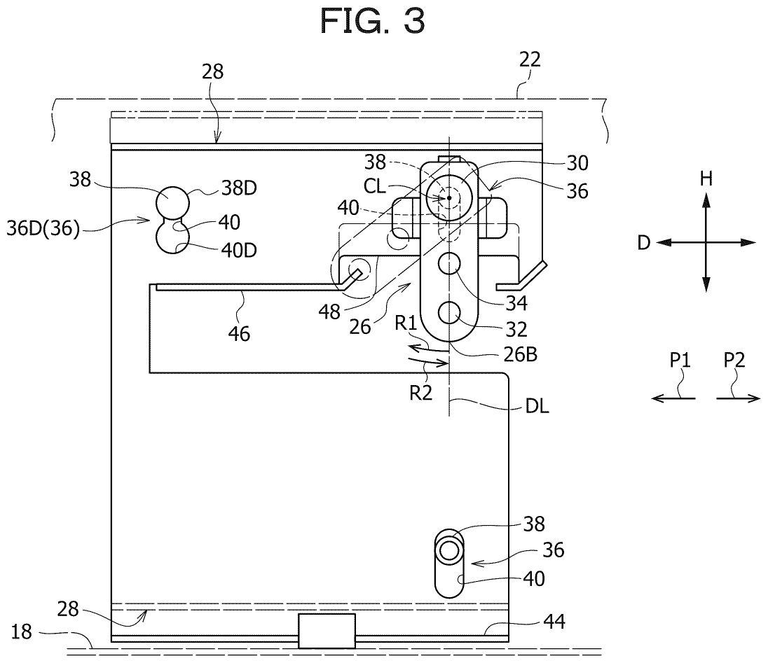

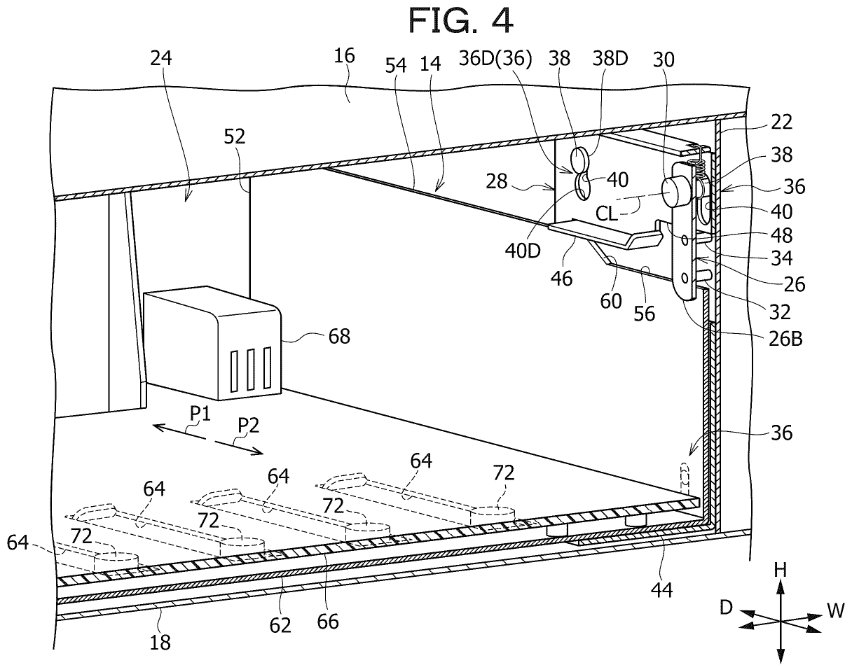

As illustrated in FIG. 2, levers 26 and movable rails 28 are provided on surfaces of the two partition walls 22 facing each other. As illustrated in FIGS. 3 and 4, the lever 26 is rotatably supported by the partition wall 22 via a rotation shaft 30. In the present embodiment, the lever 26 is a rod-shaped member of which one end side is rotatably supported by the rotation shaft 30 and the other end (lower end 26B) side extends downward from the rotation shaft 30 (rotation center). An axial direction of the rotation shaft 30 coincides with the width direction (arrow W direction) of the electronic device housing 12, and a center line CL of the rotation center of the lever 26 extends along the width direction. By the rotation of the lever 26, the lower end 26B of the lever 26 moves in the depth direction (arrow R1 direction) and an opposite direction (arrow R2 direction).

A first pin 32 and a second pin 34 are provided in the lever 26. In the present embodiment, the first pin 32 is provided at a position close to the lower end 26B of the lever 26. The second pin 34 is provided at a position closer to the rotation shaft 30 than the first pin 32 over a radial line DL coupling the center line CL of rotation and the first pin 32. As illustrated in FIG. 4, in one lever 26, the first pin 32 and the second pin 34 protrude from the lever 26 in an identical direction, for example, in any of left and right directions in FIG. 4. As will be described later, the first pin 32 is at a height position where a contact portion 54 of the electronic unit 14 comes into contact with the first pin 32 when the electronic unit 14 is inserted into the insertion portion 24. While the first pin 32 and the second pin 34 may fix a member formed separately from the lever 26 to the lever 26 by adhesion or the like, in a case where the lever 26 is made of, for example, a metal plate material, the first pin 32 and the second pin 34 may be formed by cutting and raising a part of the plate material. In a case where the lever 26 is made of resin, the lever 26, the first pin 32, and the second pin 34 may be integrally molded.

The movable rail 28 is attached to the partition wall 22 by a guide member 36. The guide member 36 supports the movable rail 28 so as to be movable up and down with respect to the insertion portion 24. A plurality of guide members 36, for example, three guide members 36 in the present embodiment, are provided for one partition wall 22. These guide members 36 are disposed apart from each other in the depth direction and an upper-lower direction.

The guide members 36 each include a housing pin 38 and an elongated hole 40. The housing pin 38 protrudes from the partition wall 22 toward the movable rail 28. The housing pin 38 is fixed to the partition wall 22 and is immovable in the upper-lower direction and the depth direction. The elongated hole 40 penetrates the movable rail 28 with the upper-lower direction as a longitudinal direction. The housing pin 38 is housed in the elongated hole 40. The movable rail 28 is movable in the upper-lower direction within a range of the elongated hole 40.

Among the plurality of guide members 36, the guide member 36 located on the far side in the insertion direction is referred to as a guide member 36D. In this guide member 36D, a large-diameter portion 38D is provided at a distal end of the housing pin 38, and a large-diameter hole 40D is formed at a lower end of the elongated hole 40. The large-diameter hole 40D has a smaller diameter than the large-diameter portion 38D, and the housing pin 38 may be housed in the elongated hole 40 by inserting the large-diameter portion 38D into the large-diameter hole 40D. In a state where the movable rail 28 has moved downward, the movable rail 28 may not come off the housing pin 38 by the large-diameter portion 38D of the housing pin 38.

As illustrated in FIG. 4, the housing pin 38 located on the near side and an upper side in the insertion direction is coaxial with the rotation shaft 30. A spring 42 is stretched between the rotation shaft 30 and the movable rail 28, and the spring 42 applies a downward force to the movable rail 28.

A support plate 44 is formed at a lower portion of the movable rail 28. The support plate 44 is a plate-shaped portion that supports the electronic unit 14. For example, the electronic unit 14 slides in the depth direction in a state of being supported by the support plate 44, and thus, the electronic unit 14 is inserted into and removed from the insertion portion 24. An upper surface of the support plate 44 comes into surface contact with a bottom plate 62 of the electronic unit 14. The “surface contact” includes not only a case where the upper surface comes into contact with the bottom plate in a continuous range extending in the depth direction and the width direction but also a case similar to a case where the upper surface substantially comes into contact with the bottom plate by bringing the upper surface into contact with the bottom plate at a plurality of points or lines.

An intermediate portion of the movable rail 28 in the upper-lower direction is cut out from the near side to the far side. A facing plate 46 is formed on an upper side of the cut portion. The facing plate 46 faces the electronic unit 14 (for example, contact portion 54 to be described later) in the middle of insertion into the insertion portion 24 from above with a slight gap therebetween.

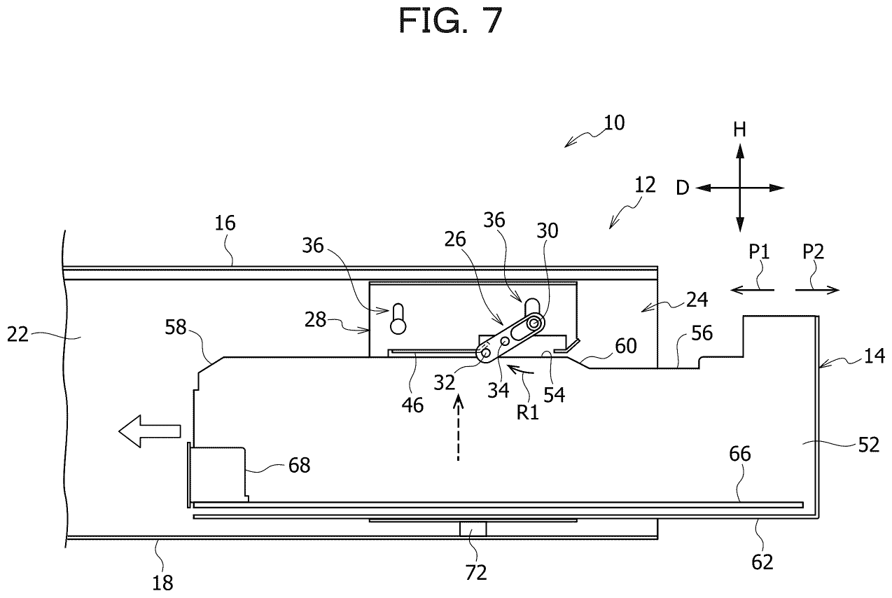

A contact side 48 is formed on the near side of the facing plate 46. The second pin 34 comes into contact with the contact side 48 from below. As illustrated in FIG. 7, when the lever 26 rotates in the arrow R1 direction and the second pin 34 moves in an arc-shaped trajectory toward the far side and the upper side, the movable rail 28 moves in an upper direction within the range of the elongated hole 40, as illustrated by a dashed double-dotted line in FIG. 3. When the electronic unit 14 is housed in a housing portion, the raised height of the movable rail 28 is secured to a height that the electronic unit 14 does not come into contact with the projection 72.

As illustrated in FIG. 2, the electronic unit 14 includes side walls 52 on respective sides in the width direction. The contact portion 54 and a contact release portion 56 are provided on an upper side of the side wall 52. The contact portion 54 is located on the far side in the depth direction, and the contact release portion 56 is located on the near side in the depth direction. The contact release portion 56 is located at a position lower than the contact portion 54.

In a case where the electronic unit 14 is inserted into the insertion portion 24, the contact portion 54 is a portion that comes into contact with the first pin 32 from below and rotates the lever 26 in the arrow R1 direction. With the contact by the contact portion 54, the first pin 32 is maintained in a state of being raised obliquely toward the far side. The contact release portion 56 is a portion that releases the contact with the first pin 32 in a state where the electronic unit 14 is further inserted into the insertion portion 24. With the contact release by the contact release portion 56, the lever 26 rotates in the arrow R2 direction, and the first pin 32 is maintained in a state of being lowered.

A first inclined portion 58 and a second inclined portion 60 are further provided in the side wall 52 of the electronic unit 14. The first inclined portion 58 is located on the far side in the insertion direction with respect to the contact portion 54. The first inclined portion 58 is obliquely raised from the far side toward the near side and is continuous with the contact portion 54.

In a case where the electronic unit 14 is inserted into the insertion portion 24, the first inclined portion 58 is a portion that first comes into contact with the first pin 32. Since the first inclined portion 58 is obliquely raised from the far side toward the near side, the first pin 32 may be gradually raised with the insertion of the electronic unit 14 into the insertion portion 24.

The second inclined portion 60 is obliquely lowered toward the near side between the contact portion 54 and the contact release portion 56, and is continuous with the contact portion 54 and the contact release portion 56. Since the second pin 34 is obliquely lowered from the far side toward the near side, the first pin 32 may be gradually lowered with the insertion of the electronic unit 14 into the insertion portion 24.

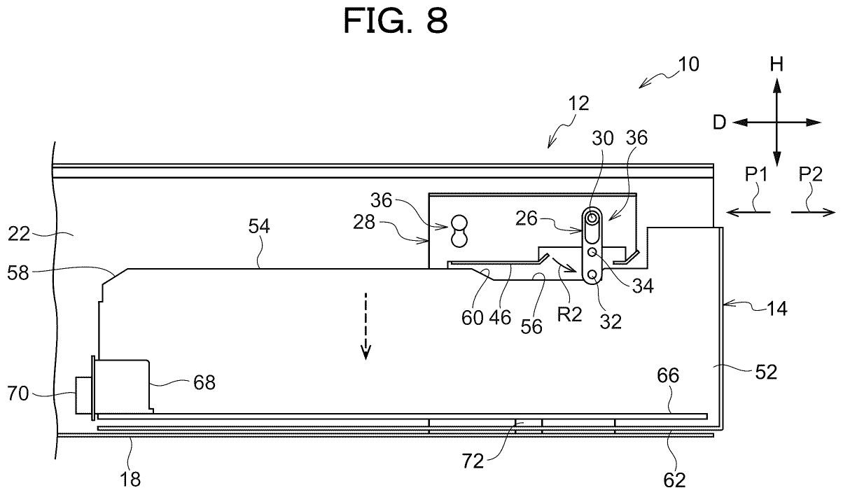

Through-holes 64 are formed in the bottom plate 62 of the electronic unit 14. As illustrated in FIGS. 4 and 8, the projection 72 is housed in the through-hole 64 from below in a state where the electronic unit 14 is inserted to a predetermined position of the insertion portion 24. For example, even though the bottom plate 62 is located below an upper end of the projection 72, interference between the projection 72 and the bottom plate 62 is avoided. The bottom plate 62 of the electronic unit 14 is, for example, a metal plate material forming a part of the housing of the electronic unit 14.

Within the electronic unit 14, a substrate 66 is supported on an upper side of the bottom plate 62. A connector 68 is attached to the substrate 66. In contrast, a connector 70 (see FIG. 8) to which the connector 68 is coupled is attached to the electronic device housing 12. In a state where the electronic unit 14 inserted at a predetermined position within the insertion portion 24, the connector 68 is electrically coupled to the connector 70.

Next, operations according to the present embodiment will be described.

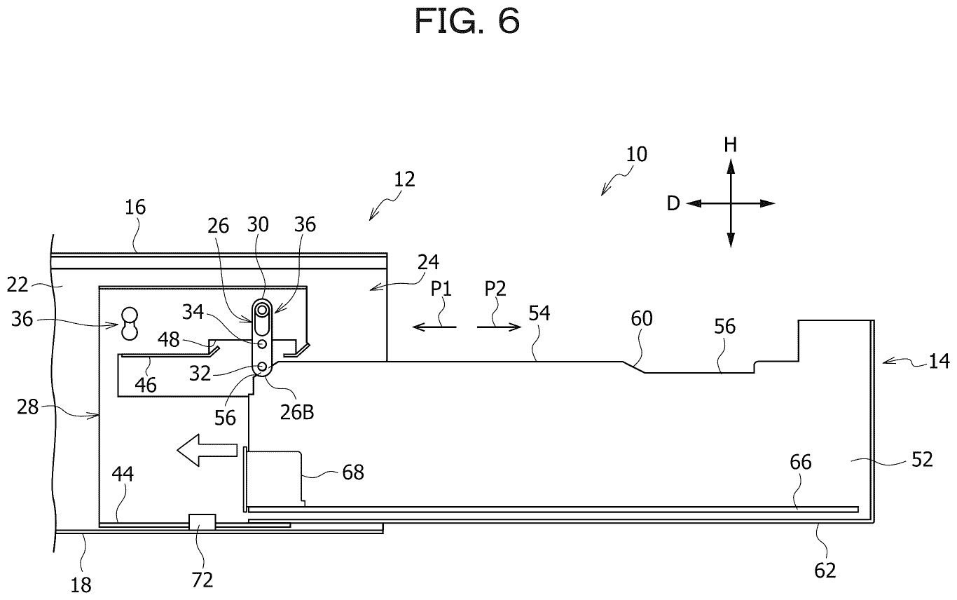

As illustrated in FIG. 6, in a state where the electronic unit 14 is not inserted into the insertion portion 24, the first pin 32 does not move to the far side. The lever 26 is in a posture in which the lower end 26B extends downward from the rotation shaft 30. The movable rail 28 is also at a lowered position in a range where the housing pin 38 is housed in the elongated hole 40. In this state, the electronic unit 14 may be supported by the support plate 44 of the movable rail 28 and may be slid toward the far side.

As illustrated in FIG. 7, when the electronic unit 14 is moved toward the far side, the first inclined portion 58 of the electronic unit 14 comes into contact with the first pin 32 in the middle of insertion of the electronic unit 14 inserted into the insertion portion 24. The electronic unit 14 is further moved toward the far side, and thus, the first pin 32 is pressed toward the far side and the lever 26 rotates in the arrow R1 direction.

By the rotation of the lever 26 in the arrow R1 direction, the second pin 34 is also raised. Since the second pin 34 comes into contact with the contact side 48 of the movable rail 28 from below, the movable rail 28 is also raised by the rising of the second pin 34. With the raising of the movable rail 28, the electronic unit 14 supported by the support plate 44 of the movable rail 28 is also raised.

In a state where the electronic unit 14 further moves toward the far side and the contact portion 54 is in contact with the first pin 32, the movable rail 28 is at the raised position. While maintaining the raised position, the electronic unit 14 is also movable toward the far side. The raised height of the electronic unit 14 is secured to a height at which the electronic unit 14 does not interfere with the projection 72. Consequently, the electronic unit 14 is inserted toward the far side within the insertion portion 24 while maintaining a predetermined height position without interfering with the projection 72. At this time, since the upper surface of the support plate 44 is in surface contact with the electronic unit 14, rattling of the electronic unit 14 is suppressed. Since the facing plate 46 of the movable rail 28 faces the contact portion 54 with a slight gap therebetween, the rattling of the electronic unit 14 is also suppressed, and the electronic unit 14 may be inserted into the insertion portion 24 in a stable posture.

When the electronic unit 14 further moves toward the far side and the second inclined portion 60 reaches the position of the first pin 32, the first pin 32 moves in a lower direction and the lever 26 rotates in the arrow R2 direction. Since the second pin 34 is also lowered, the movable rail 28 and the electronic unit 14 are also lowered.

As illustrated in FIG. 8, when the contact release portion 56 reaches the position of the first pin 32, the lever 26 is brought into a posture in which the lever 26 extends in the lower direction from the rotation shaft 30, and the movable rail 28 and the electronic unit 14 are maintained in the state of being lowered. While the bottom plate 62 of the electronic unit 14 is at a position lower than the upper end of the projection 72 at this stage, since the projection 72 is housed in the through-hole 64 formed in the bottom plate 62, the projection 72 and the bottom plate 62 do not interfere with each other.

In this way, the electronic unit 14 is inserted to a predetermined position within the insertion portion 24. In the inserted state, the connector 68 of the electronic unit 14 is electrically coupled to the connector 70 of the electronic device housing 12. The coupling of the connectors 68 and 70 by using the operation of inserting the electronic unit 14 into the insertion portion 12 may be referred to as “plug-in coupling”.

In a case where the electronic unit 14 is removed (pulled out) from the insertion portion 24, the second inclined portion 60 comes into contact with the first pin 32 in the middle of the removal, and the lever 26 rotates in the arrow R2 direction. Since the second pin 34 pushes up the movable rail 28, the electronic unit 14 is also raised. In a state where the contact portion 54 is in contact with the first pin 32, since the movable rail 28 and the electronic unit 14 are maintained in the state of being raised, the electronic unit 14 may be pulled out from the insertion portion 24 without interfering with the projection 72.

When the electronic unit 14 further moves toward the near side and the first inclined portion 58 reaches the position of the first pin 32, the first pin 32 moves in the lower direction and the lever 26 rotates in the arrow R1 direction. Since the second pin 34 is also lowered, the movable rail 28 and the electronic unit 14 are also lowered. When the first inclined portion 58 is separated from the first pin 32, the lower end 26B of the lever 26 returns to a posture of extending downward from the rotation shaft 30.

As described above, in the present embodiment, even in a case where the projection 72 is present within the insertion portion 24, the electronic unit 14 does not interfere with the projection 72 at the time of insertion. For example, even in a case where a worker is not conscious of the presence of the projection 72, the worker may insert and remove the electronic unit 14 over the projection 72 only by moving the electronic unit 14 in the depth direction with respect to the insertion portion 24. Without reducing the size of the electronic unit 14 by limiting the height thereof such that the electronic unit 14 does not interfere with the projection 72, the electronic unit 14 may be inserted into a predetermined position of the insertion portion 24.

The height of the electronic unit 14 is no longer limited, and thus, limitations on the number and sizes of components to be mounted on the electronic unit 14 are also reduced. A spatial margin is generated within the electronic unit 14, and thus, the resistance of an air flow is reduced. As a result, it is also possible to suppress deterioration in cooling performance.

In the present embodiment, the lever 26 is the rod-shaped member. As the lever 26, the lever 26 may rotate by the movement of the first pin 32 toward the far side, and the second pin 34 may be moved upward by the rotation of the lever 26. Therefore, the lever of the disclosed technology may be a plate such as a circular plate or a fan-shaped plate with the rotation shaft 30 as a center. The size of the lever 26 may be reduced by using the rod-shaped member as in the embodiment described above. With the structure in which the lever 26 extends downward from the rotation shaft 30 (rotation center), it is possible to realize a structure in which the electronic unit 14 sliding below the rotation shaft 30 comes into contact with the first pin 32 of the lever 26.

In the present embodiment, the first pin 32 is provided at a position closer to the lower end 26B of the lever 26 than the second pin 34. Since the electronic unit 14 is slid with respect to the insertion portion 24 below the lever 26, it is possible to realize a structure in which the first pin 32 easily comes into contact with the contact portion 54 without excessively lengthening the lever 26.

In the present embodiment, the first pin 32 and the second pin 34 are disposed over one radial line DL. For example, the first pin 32 and the second pin 34 are formed without deviation in a circumferential direction with the rotation shaft 30 as the center (center line CL). However, in the technology of the present disclosure, the first pin 32 and the second pin 34 may be disposed at positions deviated from each other in the circumferential direction. When the first pin 32 and the second pin 34 are at positions deviated from each other in the circumferential direction, the size of the lever 26 increases in the circumferential direction (for example, the lever 26 has a fan shape). The first pin 32 and the second pin 34 are disposed over one radial line DL as in the present embodiment, and thus, the first pin 32 and the second pin 34 may be disposed even in the rod-shaped lever 26.

In the present embodiment, in each of the levers 26, the first pin 32 and the second pin 34 protrude from the lever 26 in the identical direction. However, in the technology of the present disclosure, a structure may be employed in which the first pin 32 and the second pin 34 protrude in opposite directions in one lever 26. When the first pin 32 and the second pin 34 protrude from the lever 26 in the identical direction as in the present embodiment, a thickness of a member including the lever 26, the first pin 32, and the second pin 34 may be reduced.

In the present embodiment, the plurality of guide members 36 are provided in one movable rail 28. Compared with a structure in which one guide member 36 is provided in one movable rail 28, the movable rail 28 may be stably supported so as to be movable in the upper-lower direction. In the present embodiment, since the plurality of guide members 36 are disposed so as to be separated from each other in the depth direction (the insertion direction of the electronic unit 14), the movable rail 28 may be supported more stably than in a structure in which the guide members 36 are disposed so as not to be separated from each other in the depth direction.

In the present embodiment, the guide member 36 includes the housing pin 38 and the elongated hole 40. As the guide member of the technology of the present disclosure, a structure may be employed in which a rail-shaped member that supports the movable rail 28 so as to be slidable in the upper-lower direction is further provided on the partition wall 22 of the electronic device housing 12. When the housing pin 38 is housed in the elongated hole 40 as in the present embodiment described above, the movable rail 28 may be supported to be movable in the upper-lower direction with a simple structure.

In the present embodiment, the contact side 48 may be provided in the movable rail 28. The second pin 34 comes into contact with the contact side 48 from below. Consequently, in a case where the second pin 34 is raised, it is possible to realize a structure in which the movable rail 28 is reliably pushed up by the second pin 34.

In the present embodiment, the movable rail 28 includes the support plate 44. The support plate 44 supports the bottom plate 62 of the electronic unit 14, for example, a bottom surface. Consequently, it is possible to realize a structure in which the electronic unit 14 is supported by the movable rail 28 without newly providing the electronic unit 14 with a member for being supported by the movable rail 28.

In the present embodiment, the electronic unit 14 includes the contact portion 54 and the contact release portion 56. In a state where the electronic unit 14 is being inserted into the insertion portion 24, the contact portion 54 comes into contact with the first pin 32. Consequently, the lever 26 may be rotated in the arrow R1 direction (see FIG. 3) by pushing the first pin 32 toward the far side. In a state where the electronic unit 14 is further inserted into the insertion portion 24, the contact release portion 56 releases the contact with the first pin 32. Consequently, it is possible to rotate the lever 26 in the arrow R2 direction (refer to FIG. 2), for example, to return the posture of the lever 26 without pressing the first pin 32 to the far side.

In the present embodiment, the electronic unit 14 includes the first inclined portion 58 and the second inclined portion 60. Since the first inclined portion 58 comes into contact with the first pin 32 in an initial stage in which the electronic unit 14 is inserted into the insertion portion 24, the first pin 32 may be gradually raised with the insertion of the electronic unit 14 into the insertion portion 24. In a case where the first pin 32 is separated from the contact portion 54 and is lowered in the middle of the insertion of the electronic unit 14 into the insertion portion 24, the first pin 32 may be gradually lowered due to the second inclined portion 60. Since the second inclined portion 60 comes into contact with the first pin 32 in an initial stage in which the electronic unit 14 is removed from the insertion portion 24, the first pin 32 may be gradually raised with the removal of the electronic unit 14 from the insertion portion 24. In a case where the first pin 32 is separated from the contact portion 54 and is lowered in a final stage in which the electronic unit 14 is removed from the insertion portion 24, the first pin 32 may be gradually lowered due to the first inclined portion 58.

Although the embodiment of the technology disclosed in the present application has been described above, the technology disclosed in the present application is not limited to the above description. Of course, in addition to the above description, the technology disclosed in the present application may be varied and carried out in a variety of manners without departing from the gist thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device housing, comprising:
a lever that is rotatably attached to an insertion portion into which an electronic unit is to be inserted;
a movable rail that supports the electronic unit so as to be slidable in an insertion direction within the insertion portion;
a guide member that guides the movable rail so as to be movable up and down with respect to the insertion portion;
a first pin that is provided in the lever and rotates the lever by being moved toward a far side of the insertion portion; and
a second pin that is provided in the lever and pushes up the movable rail in accordance with the rotation.

2. The electronic device housing according to claim 1, wherein
the second pin releases the pushing-up of the movable rail in accordance with the rotation.

3. The electronic device housing according to according to claim 1, wherein
the lever extends downward from a center of the rotation.

4. The electronic device housing according to claim 3, wherein
the first pin is provided at a position closer to a lower end of the lever than the second pin.

5. The electronic device housing according to claim 3, wherein
the first pin and the second pin are disposed over an identical radial line with respect to the center of the rotation.

6. The electronic device housing according to claim 3, wherein
the first pin and the second pin protrude from the lever in an identical direction.

7. The electronic device housing according to claim 1, wherein
at least two guide members which include the guide member are provided so as to be separated from each other in the insertion direction with respect to the movable rail.

8. The electronic device housing according to claim 1, wherein
the guide member includes
a housing pin that is provided in one of the insertion portion and the movable rail, and
an elongated hole that is provided in the other of the insertion portion and the movable rail, houses the housing pin, and is elongated in an upper-lower direction.

9. The electronic device housing according to claim 1, wherein
a contact side with which the second pin comes into contact from below is provided in the movable rail.

10. The electronic device housing according to claim 1, wherein
the movable rail supports a bottom surface of the electronic unit.

11. An electronic device, comprising:
an electronic unit; and
an electronic device housing,
wherein the electronic device housing includes:
a lever that is rotatably attached to an insertion portion into which the electronic unit is to be inserted;
a movable rail that supports the electronic unit so as to be slidable in an insertion direction within the insertion portion;
a guide member that guides the movable rail so as to be movable up and down with respect to the insertion portion;
a first pin that is provided in the lever and rotates the lever by being moved toward a far side of the insertion portion; and
a second pin that is provided in the lever and pushes up the movable rail in accordance with the rotation.

12. The electronic device according to claim 11, wherein
the electronic unit includes
a contact portion that comes into contact with the first pin by the insertion into the insertion portion and maintains a state of moving toward the far side, and
a contact release portion that is provided on a near side of the contact portion and releases the contact with the first pin.

13. The electronic device according to claim 12, wherein
the electronic unit includes
a first inclined portion that is obliquely raised to the contact portion from the far side toward the near side on the far side with respect to the contact portion, and
a second inclined portion that is obliquely lowered to the contact release portion toward the near side between the contact portion and the contact release portion.
